(19) United States
(12) Patent Application Publication
(10) Pub. No.: US 2025/0283944 A1
(43) Pub. Date: Sep. 11, 2025

(54) DEVICE AND METHOD FOR ESTIMATING STATE OF HEALTH OF BATTERY

(71) Applicant: Korea Institute of Energy Research, Daejeon (KR)

(72) Inventors: Yu Jin SONG, Daejeon (KR); Sea Seung OH, Daejeon (KR); Kuk-Yeol BAE, Daejeon (KR)

(73) Assignee: Korea Institute of Energy Research, Daejeon (KR)

(21) Appl. No.: 18/276,216

(22) PCT Filed: Dec. 15, 2022
(86) PCT No.: PCT/KR2022/020452

§ 371 Date: Oct. 8, 2024

(51) Int. Cl. G01R 31/367; G01R 31/374

(52) U.S. Cl. CPC G01R 31/367; G01R 31/374

(57) ABSTRACT

An embodiment of the present disclosure provides a method for estimating a state of health of a battery, comprising: storing, as reference charging times, charging times measured respectively for a plurality of terminal voltage sections for a battery in a reference state of health, which is charged with a constant current; storing charging times respectively for N (N is a natural number equal to or higher than 2) terminal voltage sections as comparative charging times in a constant current charge mode of one battery and calculating ratio values of the comparative charging times to the reference charging times respectively for the N terminal voltage sections; and estimating a state of health of the one battery by inputting the N ratio values into a pre-learned machine learning model.

### TECHNICAL FIELD

The present disclosure relates to a technology for estimating a state of health of a battery.

### Background Art

As performance degradation mechanisms of a lithium-based battery, the loss of lithium inventory (LLI), the loss of active material (LAM), the ohmic resistance increase (ORI), the lithium plating, etc. are known.

The LLI, which is a main cause of a decrease of battery capacity, indicates loss of available lithium ions. It is known that the LLI is generated mainly by continuous growth of a solid electrolyte interface (SEI) layer.

The LAM indicates a structural and mechanical performance degradation of an electrode. Due to the LAM, both the capacity and the output power of a battery may be degraded. It is known that the LAM occurs together with the LLI, whereas the LLI may occur alone.

The ORI indicates a phenomenon that performance degradations of an electrode and an electrolyte material result in increases of electrons and ionic resistance of a cell. The ORI may occur due to various causes, such as the LLI, LAM, etc.

The lithium plating indicates a mechanism, in which pores of a porous material are blocked or a collector is split into thin layers, leading to the LAM. The lithium plating may aggravate the decrease of capacity of a cell and cause the growth of dendrites resulting in a short-circuit inside a cell.

A state in which performance is deteriorated due to such mechanisms may be called an aged state. An aged state may be indicated by a state of health (SOH).

As methods for estimating an SOH, the incremental capacity analysis, a method using charging current characteristics in a constant voltage mode, etc. are known.

However, the incremental capacity analysis requires numerous full charges and full discharges with a low current corresponding to 1/25 C in order to get data. For this reason, this analysis has a disadvantage that it takes a lot of time and, inevitably, there is noise in the data measurement.

In the method using charging current characteristics in a constant voltage mode, a charge in a constant current mode needs to be completed in order to measure a charging current in a constant voltage charge mode. For this reason, this method also requires a lot of time to collect data. In addition, since a partial charge in a constant current mode is performed in most of cases in the field, it is difficult to apply this method to actual products.

### DETAILED DESCRIPTION OF THE INVENTION

### Technical Problem

In this background, an aspect of the present disclosure is to provide a technology for estimating a state of health of a battery that is easy to apply to actual products. Another aspect of the present disclosure is to provide a technology to reduce time for estimating a state of health of a battery.

### Technical Solution

To this end, in an aspect, the present disclosure provides a method for estimating a state of health of a battery, comprising: storing, as reference charging times, charging times measured respectively in a plurality of terminal voltage sections for a battery in a reference state of health, which is charged with a constant current; storing charging times respectively of N (N is a natural number equal to or higher than 2) terminal voltage sections as comparative charging times in a constant current charge mode of one battery and calculating ratio values of the comparative charging times to the reference charging times respectively for the N terminal voltage sections; and estimating a state of health of the one battery by inputting the N ratio values into a pre-learned machine learning model.

According to the method, in estimating a state of health of the one battery, a difference between an operation temperature of the one battery and a reference temperature may additionally be inputted into the machine learning model.

The sizes of the respective N terminal voltages sections may be identical.

According to the method, in estimating a state of health of the one battery, at least one terminal voltage value corresponding to the N terminal voltage sections may additionally be inputted into the machine learning model.

According to the method, in calculating ratio values, N voltage sections from a terminal voltage of the one battery checked at a time point may be set as the N terminal voltage sections.

According to the method, in a case when the comparative charging times are measured with respect to M (M is a natural number higher than N) terminal voltage sections, the N terminal voltage sections may be set to include predetermined terminal voltage sections in calculating ratio values.

Among the M terminal voltage sections, charging time in one terminal voltage section belonging to the N terminal voltage sections may be longer than charging time in another terminal voltage section that does not belong to the N terminal voltage sections.

The machine learning model may comprise N sub machine learning models combined in a form of an ensemble, wherein each of the sub machine learning models takes a ratio value of each terminal voltage section as an input and takes a state of health value as an output.

The machine learning model may comprise L (L is a natural number higher than N) sub machine learning models, each of which takes a ratio value of each terminal voltage section as an input and takes a state of health value as an output, each sub machine learning model may have its own order of priority, and, according to the method, in estimating a state of health, the state of health of the one battery may be estimated by a value outputted from a sub machine learning model having the highest order of priority among values outputted from N sub machine learning models, corresponding to the N terminal voltage sections, among the L sub machine learning models.

At least two of the N terminal voltage sections may have different sizes and reference charging times or comparative charging times in the at least two terminal voltage sections may have sizes similar to each other within a predetermined margin of error.

In another aspect, the present disclosure provides a device for estimating a state of health of a battery, comprising: a storage circuit to store, as reference charging times, charging times measured respectively for a plurality of terminal voltage sections for a battery in a reference state of health, which is charged with a constant current; a calculation circuit to store, as comparative charging times, charging times respectively for N (N is a natural number equal to or higher than 2) terminal voltage sections in a constant current charge mode of one battery and to calculate ratio values of the comparative charging times to the reference charging times respectively for the N terminal voltage sections; and a state estimation circuit to estimate a state of health of the one battery by inputting the N ratio values into a pre-learned machine learning model.

The state estimation circuit may estimate a state of health of the one battery by additionally inputting, into the machine learning model, a difference between an operation temperature of the one battery and a reference temperature.

The state estimation circuit may estimate a state of health of the one battery by additionally inputting, into the machine learning model, at least one terminal voltage value corresponding to the N terminal voltage sections.

The calculation circuit may set N voltage sections from a terminal voltage of the one battery, which is checked at a time point, as the N terminal voltage sections.

In a case when the comparative charging times are measured with respect to M (M is a natural number higher than N) terminal voltage sections, the calculation circuit may set the N terminal voltage sections to include predetermined terminal voltage sections.

In still another aspect, the present disclosure provides a method for estimating a state of health of a battery, comprising: calculating change rates over time of terminal voltages respectively for N (N is a natural number higher than 2) terminal voltage sections in a constant current charge mode of one battery; and estimating a state of health of the one battery by comparing the calculated N change rates over time of terminal voltages with data of change rates over time of terminal voltages stored depending on states of health.

The data of change rates over time of terminal voltages may comprise lookup tables in which change rates over time of terminal voltages in a plurality of terminal voltage sections are stored depending on states of health.

According to the method, in estimating a state of health, data, including change rates over time of terminal voltages having a high similarity to the calculated N change rates over time of terminal voltages, may be searched for in the lookup tables and a state of health value corresponding to the data may be determined as a state of health value of the one battery.

According to the method, in estimating a state of health, Euclidean distance values may be calculated with respect to the calculated N change rates over time of terminal voltages and the change rates over time of terminal voltages stored in the lookup tables, data having the smallest Euclidean distance value may be searched for, and a state of health value corresponding to the data may be determined as a state of health of the one battery.

Ranges of the plurality of terminal voltage sections corresponding to the lookup tables may be wider than a range of the N terminal voltage sections regarding which calculations are performed for the one battery.

The lookup tables are stored by temperatures and, in estimating a state of health, a lookup table corresponding to a temperature of the one battery may be selected among the lookup tables included in data of the change rates over time of terminal voltages and a state of health of the one battery may be determined based on the selected lookup table.

At least two of the N terminal voltage sections may have different sizes.

Among the at least two terminal voltage sections, a terminal voltage section, where a change rate over time of a terminal voltage is large, may have a size smaller than a size of a terminal voltage section, where a change rate over time of a terminal voltage is small.

The data of the change rates over time of terminal voltages may be data obtained by measurements regarding the one battery and batteries of the same kind depending on charge and discharge cycles.

In still another aspect, the present disclosure provides a device for estimating a state of health of a battery, comprising: a measurement circuit to count charging times and to record terminal voltage values of one battery in a constant current charge mode of the one battery; a storage circuit to store data of change rates over time of terminal voltages in which change rates over time of terminal voltages for a plurality of terminal voltage sections are recorded depending on states of health; and a state estimation circuit to estimate a state of health of the one battery by calculating change rates over time of terminal voltages in respective N (N is a natural number equal to or higher than 2) terminal voltage sections by using the charging times and the terminal voltage values and comparing the calculated N change rates over time of terminal voltages with the data of change rates over time of terminal voltages.

The data of change rates over time of terminal voltages may comprise lookup tables in which change rates over time of terminal voltages in a plurality of terminal voltage sections are stored depending on states of health.

The state estimation circuit may search for, in the lookup tables, data including change rates over time of terminal voltages having a high similarity to the calculated N change rates over time of terminal voltages and determine a state of health value corresponding to the data as a state of health value of the one battery.

The state estimation circuit may calculate Euclidean distance values with respect to the calculated N change rates over time of terminal voltages and the change rates over time of terminal voltages stored in the lookup tables and determine a state of health value, corresponding to data having a smallest Euclidean distance value, as a state of health value of the one battery.

The lookup tables may be stored by temperatures, the state estimation circuit may select a lookup table corresponding to a temperature of the one battery among the lookup tables included in data of the change rates over time of terminal voltages, and determine a state of health of the one battery based on the selected lookup table.

At least two of the N terminal voltage sections may have different sizes.

### Effects of the Invention

As described above, according to the present disclosure, a technology with high accuracy for estimating a state of health of a battery may easily be applied to actual products. In addition, according to the present disclosure, time for estimating a state of health may be reduced.

### BRIEF DESCRIPTION OF THE DRAWINGS

FIG. 1 is a configuration diagram of a battery charge system according to the present disclosure.

FIG. 2 is a graph showing that constant current charging time in a predetermined terminal voltage section varies depending on a state of health (SOH).

FIG. 3 is a diagram illustrating a method for estimating an SOH based on a predetermined charging time.

FIG. 4 is a configuration diagram of a device for estimating a state of health of a battery according a first embodiment.

FIG. 5 is a configuration diagram of a first example of a machine learning model according to a first embodiment.

FIG. 6 is a diagram illustrating a terminal voltage range of reference data and terminal voltage ranges for vectors to be inputted into a machine learning model.

FIG. 7 is a diagram showing a change in charging time depending on terminal voltage ranges.

FIG. 8 is a diagram illustrating an example of selecting a terminal voltage range, regarding which an input into a machine learning model is made, among terminal voltage ranges for which comparative charging times are measured.

FIG. 9 is a configuration diagram of a second example of a machine learning model according to a first embodiment.

FIG. 10 is a configuration diagram of a third example of a machine learning model according to a first embodiment.

FIG. 11 is a configuration diagram of a fourth example of a machine learning model according to a first embodiment.

FIG. 12 is configuration diagram of a fifth example of a machine learning model according to a first embodiment.

FIG. 13 is a flow diagram illustrating a method for estimating a state of health of a battery according to a first embodiment.

FIG. 14 is a flow diagram illustrating a method for estimating a state of health of a battery according to a second embodiment.

FIG. 15 is an example of a lookup table of a second embodiment, in which change rates over time of terminal voltages are stored depending on the number of charges and discharges.

FIG. 16 is an example of lookup tables in a second embodiment, in which change rates over time of terminal voltages are stored depending on temperatures.

FIG. 17 is a diagram illustrating a process of searching for data most similar to change rates over time of terminal voltages of a subject battery in a second embodiment.

FIG. 18 is a flow diagram of a method for estimating a state of health of a battery according to a second embodiment.

### MODE FOR IMPLEMENTING THE INVENTION

Hereinafter, some embodiments of the present disclosure will be described in detail with reference to the accompanying drawings. With regard to the reference numerals of the components of the respective drawings, it should be noted that the same reference numerals are assigned to the same components even though they are shown in different drawings. In addition, in describing the present disclosure, a detailed description of a well-known configuration or function related the present disclosure, which may obscure the subject matter of the present disclosure, will be omitted.

In addition, terms, such as “1st”, “2nd”, “A”, “B”, “(a)”, “(b)”, or the like, may be used in describing the components of the present disclosure. These terms are intended only for distinguishing a corresponding component from other components, and the nature, order, or sequence of the corresponding component is not limited to the terms. In the case where a component is described as being “coupled”, “combined”, or “connected” to another component, it should be understood that the corresponding component may be directly coupled or connected to another component or that the corresponding component may also be “coupled”, “combined”, or “connected” to the component via another component provided therebetween.

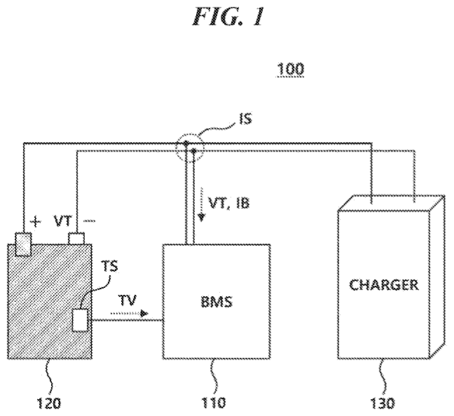

FIG. 1 is a configuration diagram of a battery charge system according to the present disclosure.

Referring to FIG. 1, the battery charge system 100 may comprise a battery 120, a battery management device 110 and a charger 130.

The battery 120 may be a lithium-based battery. The battery 120 may be a lithium-ion battery or a lithium polymer battery.

The battery 120 may comprise one cell or multiple cells. When the battery 120 comprises multiple cells, the cells may be connected in series or in parallel.

The battery 120 may be formed as a battery pack including a cell. The battery pack may further comprise a protection circuit in addition to the cell and a sensor as well, such as a temperature sensor TS.

The battery 120 may further comprise a signal transmitting and receiving circuit. The battery 120 may transmit state information of the battery 120 to an external apparatus through the signal transmitting and receiving circuit. For example, the battery 120 may transmit information TV about an operation temperature of the battery 120 to the battery management device 110 through the signal transmitting and receiving circuit.

The battery 120 may comprise terminals through which a current is inputted or outputted. For example, the battery 120 may comprise a plus terminal having a positive polarity and a minus terminal having a negative polarity. A voltage between the two terminals formed in the battery 120 may be referred to as a terminal voltage VT.

A current, which flows in or flows out from the battery 120, may be referred to as a battery current IB. A current that flows in through the plus terminal may be referred to as a charge current and a current that flows out from the plus terminal may be referred to as a discharge current.

The battery 120 and the charger 130 may be connected with each other by a cable through which the battery current IB may flow. The charger 130 may supply a charge current to the battery 120 through such a cable.

In the cable, a current sensor IS may be disposed. The battery management device 110 may measure a level of the battery current IB by using the current sensor IS. In addition, the battery management device 110 may measure a terminal voltage VT of the battery 120 by using a voltage formed in the cable.

The charger 130 may operate in a constant current charge mode, in a constant voltage charge mode, or in a constant power charge mode. The charger 130 in the constant current charge mode may make the level of a charge current, supplied to the battery 120, constant. For example, supposing that the level of a charge current capable of fully charging the battery in 1 hour is 1 C, the charger 130 in the constant current charge mode may maintain the level of a charge current to be 0.1 C or 0.2 C. The charger 130 in the constant current charge mode may maintain the charge current to be another constant level.

The charger 130 in the constant voltage charge mode may supply a charge current such that the terminal voltage VT of the battery 120 may be maintained to be constant and the charger 130 in the constant power charge mode may supply a charge current such that the magnitude of charge power supplied to the battery 120 is maintained to be constant.

The battery management device 110 may estimate a state of the battery 120 and control peripheral devices, such as the charger 130 for management of the battery 120.

The battery management device 110 may estimate a state of charge of the battery 120. The state of charge may be indicated by SOC. The battery management 110 may estimate the SOC of the battery 120 by using the charge integration, the open circuit voltage method, etc.

The battery management device 110 may estimate a residual capacity of the battery 120. The battery management device 110 may estimate the residual capacity of the battery 120 by totaling up the amount of charges discharged until the battery 120, which was fully charged, becomes fully discharged.

The battery management device 110 may estimate a state of health of the battery 120. The state of health may be indicated by SOH. In terms that it estimates the state of health of a battery 120, the battery management device 110 may be referred to as a device for estimating a state of health of a battery.

Although the descriptions below of the battery management device 110 focus on embodiments in which the battery management device 110 functions as the device for estimating a state of health of a battery, as described above, the battery management device 110 may estimate the state of charge of the battery, estimate the residual capacity of the battery or perform other functions associated with other battery management.

The SOH may be obtained by calculating a ratio between a battery capacity in a reference state and a battery capacity in a current state.

$$SOH = Ck / Ci$$

Ck: battery capacity in current state, Ci: battery capacity in reference state

The battery capacity may be defined by a total amount of discharged or charged charges.

$$Ck = \frac{{\int }_{{t}_{k}}^{{t}_{k + L}} I ( t ) dt}{{SOC}_{k} - {SOC}_{k + L}} = \frac{{\int }_{{t}_{k}}^{{t}_{k + L}} I ( t ) dt}{SOC ( {Voc}_{k} ) - SOC ( {Voc}_{k + L} )}$$

I: battery current
tₖ: first time point, t_{k+L}: second time point where a predetermined time has elapsed from the first time point
SOCₖ: battery SOC at first time point, SOC_{k+L}: battery SOC at second time point
Vocₖ: battery open voltage at first time point, Voc_{k+L}: battery open voltage at second time point

Generally, since the battery SOC may be mapped onto the Voc in 1:1 and a charge current of the battery charged in a constant current mode is constant, the battery capacity Ck in a predetermined terminal voltage section of the battery may be proportional to constant current charging time t_{k+L}−tₖ. Accordingly, the SOH of the battery may be obtained by a modified equation as follows.

$$SOH = Ck / Ci {}_{}^{\cdot } {=}_{\cdot }^{} Δ tk / Δ ti$$

Δtk: constant current charging time for a predetermined terminal voltage section in a current state
Δti: constant current charging time for a predetermined terminal voltage section in a reference state

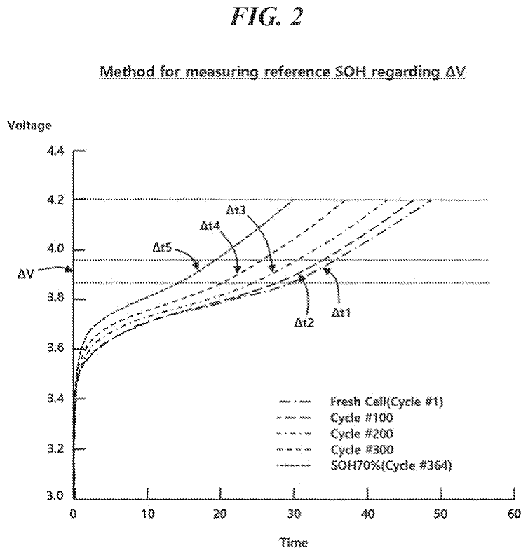

FIG. 2 is a graph showing constant current charging time in a predetermined terminal voltage section varies depending on the SOH.

Referring to FIG. 2, it can be identified that it takes a first charging time Δt1 in a predetermined terminal voltage section ΔV for charging a cell Cycle #1 in an initial state in the constant current mode, it takes a second charging time Δt2 for a cell Cycle #100, which has had 100 charges and discharges, it takes a third charging time Δt3 for a cell Cycle #200,which has had 200 charges and discharges, it takes a fourth charging time Δt4 for a cell Cycle #300, which has had 300 charges and discharges, and it takes a fifth charging time Δt5 for a cell Cycle #364 of 70% of the SOH.

It can be confirmed through FIG. 2 that, as the SOH decreases, the charging time for a predetermined terminal voltage section ΔV is shortened in consideration of the fact that the SOH generally decreases when the number of times of charges and discharges increases.

After having determined a predetermined terminal voltage section ΔV as shown in FIG. 2, the device for estimating a state of health of a battery may estimate the SOH by identifying the charging time of a battery in the reference state, for example in the initial state, corresponding to the predetermined terminal voltage section ΔV and the charging time of a battery in the current state and calculating a ratio value of the charging time of the battery in the current state to the charging time of the battery in the reference state.

As another method, the device for estimating a state of health of a battery may determine specific charging time in the constant current charge mode, and subsequently, determine a terminal voltage section corresponding to this specific charging time.

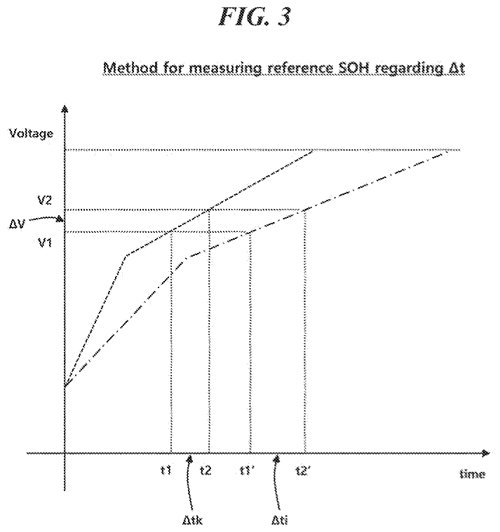

FIG. 3 is a diagram illustrating a method for estimating an SOH based on a predetermined charging time.

Referring to FIG. 3, the device for estimating a state of health of a battery may determine specific charging time Δtk first when a battery in the current state is charged with a constant current. Subsequently, the device for estimating a state of health of a battery may identify terminal voltages V1, V2 respectively at a start time t1 and an end time t2 of this specific charging time Δtk and search for a relevant terminal voltage section AV among previously stored data of a battery in the reference state. Then, the device for estimating a state of health of a battery may determine a charging time of the battery in the reference state based on a charge start time t1′ and a charge end time t2′ of the battery in the reference state, which correspond to the terminal voltage section ΔV. Lastly, the device for estimating a state of health of a battery may estimate an SOH by calculating a ratio value of the charging time of the battery in the current state to the charging time of the battery in the reference state.

When the terminal voltage section is first determined, the charging time in a specific terminal voltage section may be short and this may lead to a wide margin of error in the SOH estimation. The method shown in FIG. 3 of determining the charging time first has an advantage that the probability of such an error may be reduced.

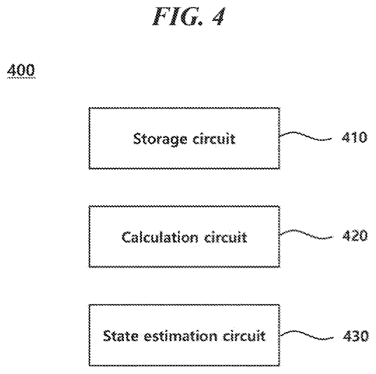

FIG. 4 is a configuration diagram of a device for estimating a state of health of a battery according a first embodiment.

Referring to FIG. 4, the device for estimating a state of health of a battery ('estimation device', hereinafter) 400 may comprise a storage circuit 410, a calculation circuit 420 and a state estimation circuit 430.

The storage circuit 410 may store charging times measured respectively in multiple terminal voltage sections for a battery in a reference state of health, which is charged with a constant current.

The reference state of health of the battery may be an initial state of the battery. A device for generating reference data may prepare a plurality of batteries in an initial state, measure reference charging times respectively for the plurality of batteries, and determine a final reference charging time through statistical processing, for example, an average calculation. The storage circuit 410 may store the reference charging time determined in this way in a memory.

The reference charging times may be measured at a reference temperature. For example, the device for generating reference data may set the reference temperature at 20 degrees Celsius and measure and record the reference charging times respectively in a plurality of terminal voltage sections for a battery charged with a constant current at 20 degrees Celsius. In this way, the storage circuit 410 may store the reference charging times, measured at the reference temperature, in the memory.

In addition, the storage circuit 410 may store, in the memory, data regarding the reference charging times recorded by the device for generating reference data.

The calculation circuit 420 may store, as comparative charging times, charging times respectively for N (N is a natural number equal to or higher than 2) terminal voltage sections of a battery, which is a subject for a state estimation, (‘subject battery’, hereinafter) in the constant current charge mode. Then, the calculation circuit 420 may calculate a ratio value of comparative charging time to the reference charging time for each of the N terminal voltage sections.

The state estimation circuit 430 may estimate a state of health of the subject battery by inputting N ratio values into a pre-learned machine learning model.

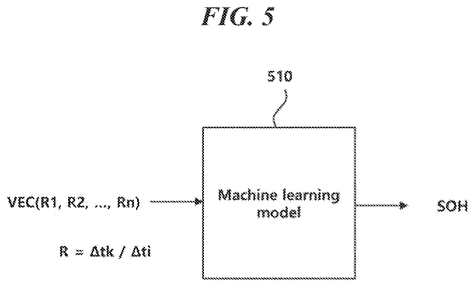

FIG. 5 is a configuration diagram of a first example of a machine learning model according to a first embodiment.

Referring to FIG. 5, N ratio values R1, R2, . . . , Rn may be inputted into a machine learning model 510.

The estimation device may calculate a first ratio value R1 of comparative charging time Δtk to the reference charging time Δti for a first terminal voltage section, a second ratio value R2 for a second terminal voltage section following the first terminal voltage section, and, sequentially in this way, an Nth ratio value Rn for a Nth terminal voltage section.

Next, the estimation device may form a vector VEC with the first ratio value R1 to the Nth ratio value Rn and input the vector VEC into the machine learning model 510.

Then, the estimation device may estimate a state of health of the subject battery with an SOH outputted from the machine learning model 510.

The estimation device may generate a vector value VEC for N consecutive terminal voltage sections of the subject battery. A terminal voltage range, for which such a vector VEC is generated, may be narrower than a terminal voltage range stored in the reference data.

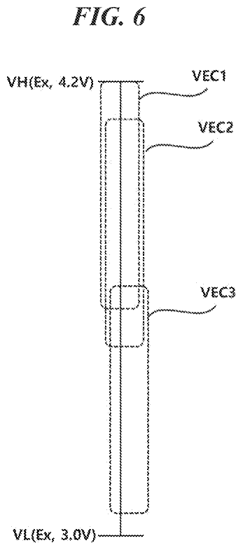

FIG. 6 is a diagram illustrating a terminal voltage range of reference data and terminal voltage ranges for vectors to be inputted into a machine learning model.

Referring to FIG. 6, a terminal voltage range of the reference charging time stored as the reference data may be wider than terminal voltage ranges of vectors inputted into the machine learning model.

For example, the terminal voltage range of the reference data may be a range of 3.0V˜ 4.2V, whereas the terminal voltage ranges of the vectors inputted into the machine learning model may correspond to parts of the range of 3.0V˜ 4.2V.

A terminal voltage range of a vector inputted into the machine learning model may vary within the terminal voltage range of the reference data. For example, a terminal voltage range of a vector may correspond to a range of voltages relatively as high as that for a first vector VEC1, to a range of voltages relatively as low as that for a third vector VEC3 or to a range of intermediate voltages as that for a second vector VEC2.

Even though a terminal voltage range of a vector is changed, the estimation device may estimate a state of health of the subject battery with relatively high accuracy. For example, either when the terminal voltage range of the vector, inputted into the machine learning model, corresponds to the terminal voltage range of the first vector VEC1 or when it corresponds to the terminal voltage range of the third vector VEC3, the relevant result values may be similar. The reason for this is that what is inputted into the machine learning model are ratio values of comparative charging times to the reference charging time in terminal voltage sections, not charging times in the terminal voltage sections.

The subject battery may be charged with a constant current in different voltage ranges depending on circumstances. Since the estimation device according to the first embodiment may estimate the state of health of the subject battery by using the vectors VEC obtained in different voltage ranges, it has an advantage that it can be applied to any of various circumstances or various applications.

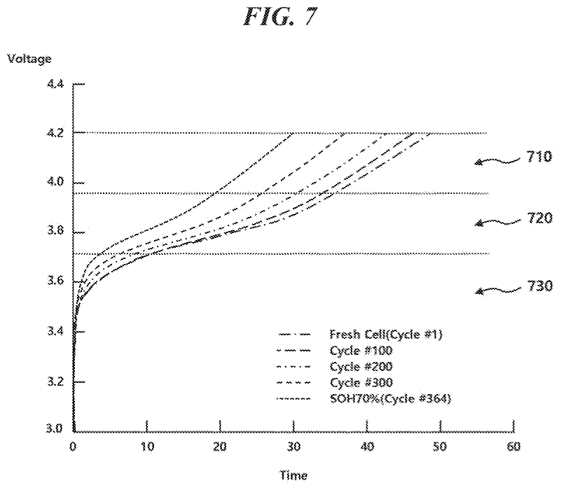

FIG. 7 is a diagram showing a change in charging time depending on terminal voltage ranges.

Referring to FIG. 7, it can be verified that, as the number of charges and discharges increases, the charging times for the same terminal voltage section are shortened.

Meanwhile, when dividing an entire terminal voltage range, regarding which reference charging time is recorded, into three ranges 710, 720, 730 and observing the three ranges, it can be verified that charging times for a unit voltage in a second range 720 are relatively longer than those in the other ranges 710, 730.

In a section where the charging times for a unit voltage are relatively long, as with the second range 720, even when there is an error in charging time due to influence of noise or environment, fluctuations in estimated values for the state of health may be small.

Accordingly, in a case when it is possible to use several ranges, the estimation device may select a range previously confirmed to provide high stability and accuracy as the second range 720 for a more stable and accurate estimation of the state of health.

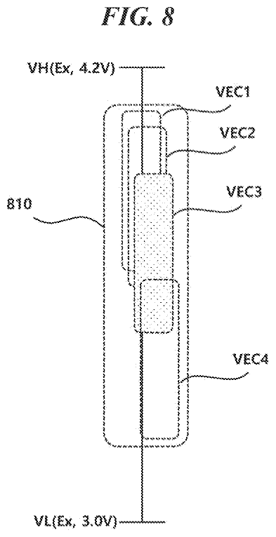

FIG. 8 is a diagram illustrating an example of selecting a terminal voltage range to be inputted into a machine learning model among terminal voltage ranges for which comparative charging times are measured.

Referring to FIG. 8, the estimation device may measure comparative charging times of the subject battery with respect to a relatively wide terminal voltage range 810. Here, the terminal voltage range 810 for the measurement may be wider than a terminal voltage range to be inputted into the machine learning model.

When a voltage range corresponding to N terminal voltage sections is inputted into the machine learning model, the terminal voltage range for the measurement may comprise M, which is greater than N, terminal voltage sections.

The estimation device may select vectors VEC1, VEC2, VEC3, VEC4 for various voltage ranges in the M terminal voltage sections. The estimation device may set N terminal voltage sections such that the N terminal voltage sections include predetermined terminal voltage sections, for example, terminal voltage sections corresponding to the VEC3 and may generate ratio values and/or the vector VEC3 for the corresponding terminal voltage sections.

As described regarding FIG. 7, a charging time for one terminal voltage section belonging to the predetermined N terminal voltage sections among the M terminal voltage sections for the measurement may be longer than charging time for another terminal voltage section that does not belong to the N terminal voltage sections.

The sizes of the respective terminal voltage sections may be identical. Otherwise, at least two terminal voltage sections among the N terminal voltage sections may have different sizes, but even in this case, reference charging times or comparative charging times in the at least two terminal voltage sections may have the same size or sizes similar to each other within a predetermined margin of error. With such an embodiment it may be understood that the concept described by referring to FIG. 3 is applied.

Conceptually, the method of estimating a state of health by calculating ratio values has an advantage that a terminal voltage range may freely be selected when compared to other methods. However, there may be some fluctuations in an estimated value depending on terminal voltage ranges. In order to compensate for this, a terminal voltage value may additionally be inputted into the machine learning model.

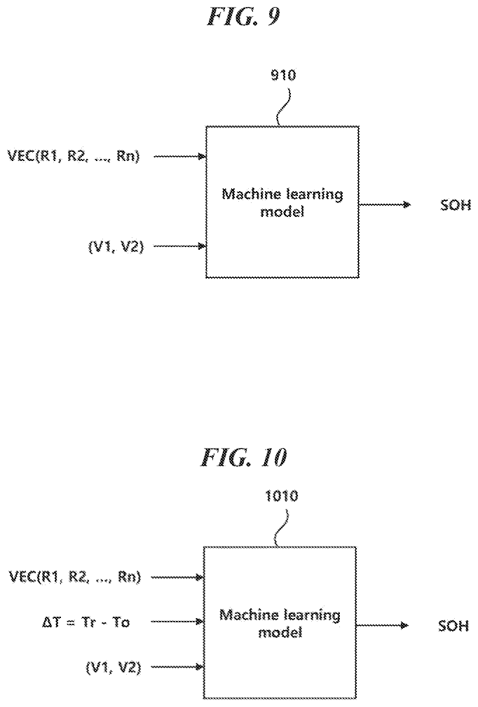

FIG. 9 is a configuration diagram of a second example of a machine learning model according to a first embodiment.

Referring to FIG. 9, a vector VEC comprising N ratio values R1, R2, . . . , Rn may be inputted into a machine learning model 910 and at least one terminal voltage value V1, V2 corresponding to the N terminal voltage sections may additionally be inputted thereinto.

Voltages V1, V2 of both ends of the N terminal voltage sections may be inputted into the machine learning model 910 or the lowest voltage V1 or the highest voltage V2 may be inputted thereinto.

In such a method in which information about voltage ranges of the terminal voltage sections inputted into the machine learning model 910 is additionally inputted, the accuracy of the estimation of the state of health may be increased.

FIG. 10 is a configuration diagram of a third example of a machine learning model according to a first embodiment.

Referring to FIG. 10, a vector VEC comprising N ratio values R1, R2, . . . , Rn may be inputted into a machine learning model 1010, at least one terminal voltage value V1, V2 corresponding to N terminal voltage sections may additionally be inputted thereinto, and a difference ΔT, between an operation temperature To of the subject battery and a reference temperature Tr at which reference charging time is recorded, may additionally be inputted thereinto.

The machine learning model may take pre-learning with comparative charging times previously measured for test batteries of the same kind as that of a subject battery.

Test batteries of the same kind as that of the subject battery may be prepared.

A machine learning model training device may measure charging time (comparative charging time for training) for each of a plurality of terminal voltage sections while charging the test batteries in the constant current mode. For example, when a plurality of terminal voltage sections at intervals of 0.1V within a range of 3.0V˜ 4.2V are formed, the machine learning model training device may measure times where terminal voltages of the test batteries, that are charged with a constant current pass the relevant sections as comparative charging times for training. In addition, the machine learning model training device may record the comparative charging times measured for the respective terminal voltage sections.

The machine learning model training device may increase the numbers of times of charges and discharges of the test batteries and record comparative charging times for training depending on the numbers of times of charges and discharges. Here, the machine learning model training device may also measure SOHs of the test batteries and record them together with the comparative charging times for training.

The machine learning model training device may measure comparative charging times for training by operation temperatures. The test batteries may be divided into several groups and the groups may separately be disposed in chambers of different temperatures. In this way, the machine learning model training device may record the comparative charging times for training depending on the temperatures.

Further, the machine learning model training device may input into the machine learning model ratio values (for training) of the comparative charging times for training to the reference charging time and tune parameters inside the machine learning model by comparing result values from the machine learning model with the pre-measured SOHs.

The machine learning model training device may input into the machine learning model the ratio values for training and the operation temperatures and/or at least one terminal voltage value of the terminal voltage sections and tune parameters inside the machine learning model by comparing result values from the machine learning model with the pre-measured SOHs.

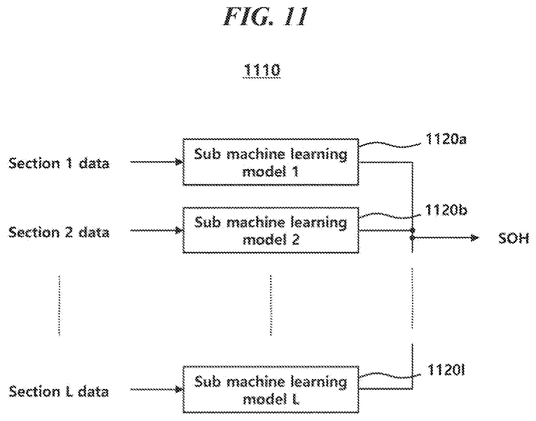

FIG. 11 is a configuration diagram of a fourth example of a machine learning model according to a first embodiment.

Referring to FIG. 11, a machine learning model 1110 may comprise L (L is a natural number equal to or higher than 2) sub machine learning models 1120a˜1120l combined in a form of an ensemble.

A first sub machine learning model 1120a may be a model trained by training data—ratio values, SOHs, operation temperatures, etc.—of a first terminal voltage section, a second sub machine learning model 1120b may be a model trained by training data—ratio values, SOHs, operation temperatures, etc.—of a second terminal voltage section, and an Lth sub machine learning model 1120l may be a model trained by training data—ratio values, SOHs, operation temperatures, etc.—of an Lth terminal voltage section.

The sub machine learning models 1120a˜1120l may be combined as a form of an ensemble, and then, may additionally be trained by training data of each terminal voltage section. Here, a weighting may be given on an output value from each sub machine learning model depending on accuracy of each sub machine learning model. Such a weighting may improve the accuracy of a final output value SOH.

The machine learning model 1110 may comprise N sub machine learning models and data, inputted into each sub machine learning model, may be ratio values calculated respectively regarding the N terminal voltage sections.

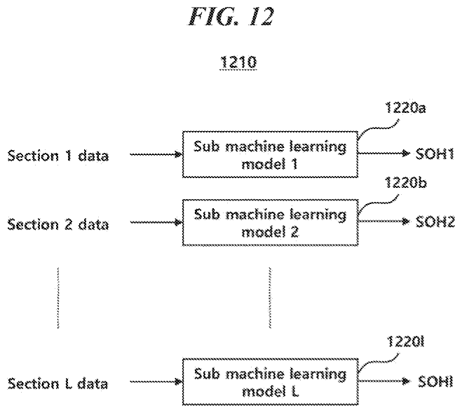

FIG. 12 is configuration diagram of a fifth example of a machine learning model according to a first embodiment.

Referring to FIG. 12, a machine learning model 1210 may comprise L (L is a natural number equal to or higher than 2) sub machine learning models 1220a˜1220l.

A first sub machine learning model 1220a may be a model trained by training data—ratio values, SOHs, operation temperatures, etc.—of a first terminal voltage section, a second sub machine learning model 1220b may be a model trained by training data—ratio values, SOHs, operation temperatures, etc.—in a second terminal voltage section, and an Lth sub machine learning model 1220l may be a model trained by training data—ratio values, SOHs, operation temperatures, etc.—in an Lth terminal voltage section.

The sub machine learning models 1120a˜1120l may respectively output SOHs. The first sub machine learning model 1220a may output a first SOH, the second sub machine learning model 1220b may output a second SOH, and the Lth sub machine learning model 1220l may output an lth SOH.

Each sub machine learning model 1120a˜ 1120l may have its own order of priority. The estimation device may use an SOH outputted from a sub machine learning model having the highest order of priority as a value of a state of health of the subject battery. Such a method has an advantage that even when input data, such as ratio values, is not generated in the entire range, but it is generated in a partial range, the state of health of the subject battery may be estimated.

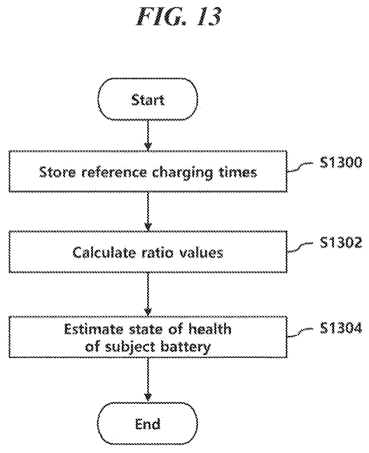

FIG. 13 is a flow diagram illustrating a method for estimating a state of health of a battery according to a first embodiment.

Referring to FIG. 13, regarding a battery in a reference state of health, which is charged with a constant current, the estimation device may store charging time measured in each of a plurality of terminal voltage sections as reference charging time S1300.

All terminal voltage sections may be the same size. Otherwise, at least two of the terminal voltage sections may have different sizes, however, reference charging times for the at least two of the terminal voltage sections may have lengths similar to each other within a predetermined margin of error.

In the constant current charge mode of the subject battery, the estimation device may store charging times respectively for N (N is a natural number equal to or higher than 2) terminal voltage sections as comparative charging times and calculate ratio values of the comparative charging times to the previously stored reference charging times for the respective N terminal voltage sections S1302.

In S1302, the estimation device may set N voltage sections from a terminal voltage of the subject battery, which is checked at one time point, as terminal voltage sections. In another aspect, the estimation device may calculate N ratio values in an arbitrary terminal voltage range.

The estimation device may measure comparative charging times for M, which is greater than N, terminal voltage sections. The estimation device may set N terminal voltage sections such that the N terminal voltage sections include predetermined terminal voltage sections. Here, charging time for one terminal voltage section belonging to the N terminal voltage sections among the M terminal voltage sections may be longer than charging time for another terminal voltage section that does not belong to the N terminal voltage sections.

The estimation device may estimate a state of health of the subject battery by inputting the calculated N ratio values into a pre-learned machine learning model S1304.

When estimating the state of health, the estimation device may estimate the state of health of the subject battery by additionally inputting into the machine learning model a difference between an operation temperature of the subject battery and a reference temperature.

When estimating the state of health, the estimation device may estimate the state of health of the subject battery by additionally inputting into the machine learning model at least one terminal voltage value corresponding to the N terminal voltage sections.

The machine learning model may comprise N sub machine learning models combined in a form of an ensemble, wherein each sub machine learning model takes a ratio value of each terminal voltage section as an input and a value of a state of health as an output.

The machine learning model may comprise L (L is a natural number equal to or higher than N) sub machine learning models, each of which takes a ratio value of each terminal voltage section as an input and a value of a state of health as an output. Here, each sub machine learning model may have its own order of priority. When estimating the state of health, the estimation device may estimate the state of health of the subject battery based on a value outputted from a sub machine learning model having the highest priority among values outputted from N sub machine learning models corresponding to the N terminal voltage sections among the L sub machine learning models.

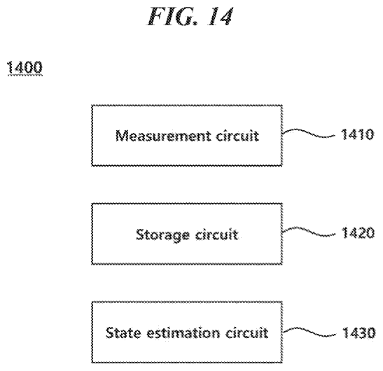

FIG. 14 is a flow diagram illustrating a method for estimating a state of health of a battery according to a second embodiment.

Referring to FIG. 14, an estimation device 1400 may comprise a measurement circuit 1410, a storage circuit 1420 and a state estimation circuit 1430.

The measurement circuit 1410 may record terminal voltage values of the subject battery by counting charging time while the subject battery is being charged in the constant current charge mode. Recorded content may be a pair of time and a voltage value, for example, in a form of (00:00:00:000, 0V).

The measurement circuit 1410 may record time and a terminal voltage every predetermined time, for example, every one second. Otherwise, the measurement circuit 1410 may record time and a terminal voltage for every predetermined voltage, for example, for every 0.1V. Otherwise, the measurement circuit 1410 may record time and a terminal voltage based on a predetermined reference. For example, the measurement circuit 1410 may record time and a terminal voltage at a predetermined specific terminal voltage or record time and a terminal voltage based on a predetermined charging time.

The storage circuit 1420 may store data of change rates over time of terminal voltages in which change rates over time of terminal voltages for a plurality of terminal voltage sections are recorded depending on states of health.

A change rate over time of a terminal voltage is a value indicating a change amount of the terminal voltage for a predetermined charging time and it may be obtained by dividing the change amount of the terminal voltage ΔV by charging time Δt.

The storage circuit 1420 may store change rates over time of terminal voltages respectively for a plurality of terminal voltage sections by increasing the numbers of times of charges and discharges of a battery of the same kind as that of the subject battery. Data stored in this way may be referred to as reference data.

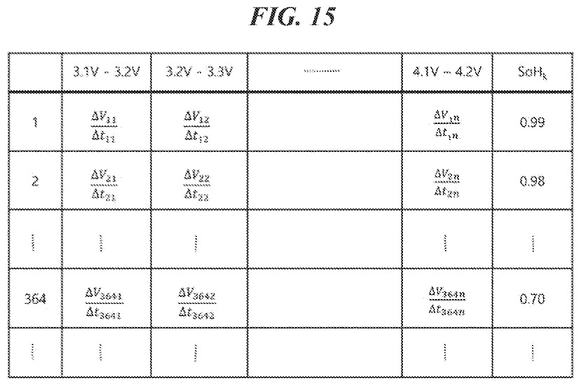

FIG. 15 is an example of a lookup table of a second embodiment in which change rates over time of terminal voltages are stored depending on the number of times of charges and discharges.

Referring to FIG. 15, the storage circuit may divide a terminal voltage into a plurality of sections and store change rates (ΔV/Δt) over time of the terminal voltages in respective terminal voltage sections.

In order to generate reference data, the storage circuit may measure and store change rates over time of terminal voltages depending on the numbers of times of charges and discharges regarding test batteries. For example, the storage circuit may store change rates over time of terminal voltages respectively in a plurality of terminal voltage sections for a test battery having one time of the charge and discharge and may store change rates over time of terminal voltages respectively in a plurality of terminal voltage sections for a test battery having 364 times of the charges and discharges.

The storage circuit may measure SOHs as well regarding the respective numbers of times of charges and discharges. For example, the storage circuit may store change rates over time of terminal voltages for a test battery having one time of the charge and discharge and measure and store SOHs as well. In addition, the storage circuit may store change rates over time of terminal voltages for a test battery having 364 charges and discharges and measure and store SOHs as well.

Data may be generated for multiple test batteries. The storage circuit may generate one piece of reference data by statistically processing data generated regarding the multiple test batteries. For example, the storage circuit may generate one piece of reference data by averaging pieces of data generated regarding the multiple test batteries.

Change rates over time of respective terminal voltage sections may be measured and stored by operation temperatures.

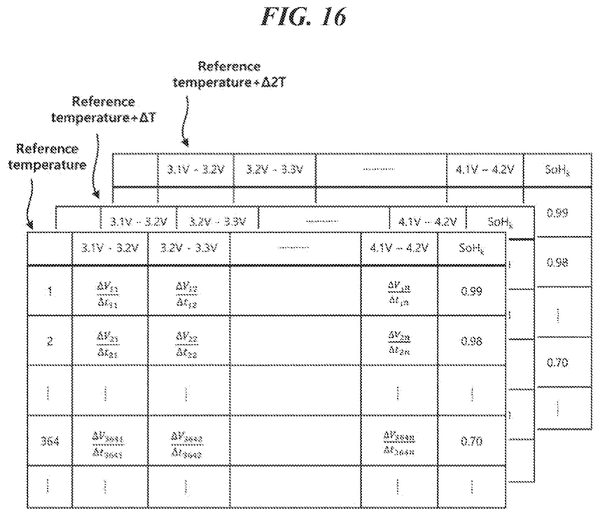

FIG. 16 is an example of lookup tables in a second embodiment, in which change rates over time of terminal voltages are stored depending on temperatures.

Referring to FIG. 16, the storage circuit may store lookup tables for respective temperatures.

Test batteries may be disposed in chambers of different temperatures and charged and discharged in different temperature conditions. In this way, values required for the above-mentioned lookup tables may be generated.

The storage circuit may classify the values generated in such a way—for example, change ranges over time in terminal voltages in respective terminal voltage sections, SOHs, etc.—by temperatures and store them by temperatures.

The estimation device may find data in a most similar state to that of the subject battery among the reference data stored in the storage circuit and estimate a state of health of the subject battery based on an SOH value corresponding to the data.

Referring to FIG. 14 again, the estimation device 1400 may comprise the measurement circuit 1410 and the storage circuit 1420 and further comprise the state estimation circuit 1430.

The state estimation circuit 1430 may calculate change rates over time of terminal voltages in respective N (N is a natural number equal to or higher than 2) terminal voltage sections by using the charging times and the terminal voltage values recorded by the measurement circuit 1410.

Then, the state estimation circuit 1430 may estimate a state of health of the subject battery by comparing the calculated N change rates over time of terminal voltages with data about the change rates over time of terminal voltages stored in the storage circuit 1420—the reference data described by referring to FIG. 15 and FIG. 16.

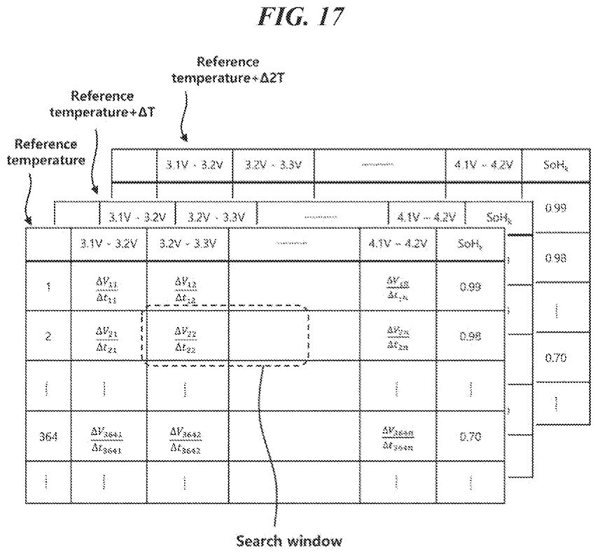

FIG. 17 is a diagram illustrating a process of searching for data most similar to change rates over time of terminal voltages of a subject battery in a second embodiment.

Referring to FIG. 17, the state estimation circuit may identify an operation temperature of the subject battery and search for a lookup table including data measured at a temperature most similar to the operation temperature. FIG. 17 shows that a reference temperature is most similar to the operation temperature of the subject battery.

After having searched for the lookup table regarding the relevant operation temperature, the state estimation circuit may identify data regarding N terminal voltage sections, among a plurality of terminal voltage sections stored in the lookup table, for which data of the subject battery has been measured. For example, supposing that the lookup table stores change rates over time of terminal voltages of a test battery regarding a plurality of terminal voltage sections corresponding to a range of 3.1V˜4.2V and the N terminal voltage sections, for which data of the subject battery has been measured, correspond to a range of 3.2V˜3.7V, the state estimation circuit may identify, in the lookup table, data of the terminal voltage sections corresponding to the range of 3.2V˜3.7V.

If a part corresponding to the N terminal voltage sections is referred to as a search window, the state estimation circuit may search for data most similar to the change rates over time of terminal voltages of the subject battery by moving the search window among data arranged by the number of times of charges and discharges. When completing the search, the state estimation circuit may determine an SOH corresponding to the identified data as a state of health value of the subject battery.

When forming change rates over time of terminal voltages regarding the N terminal voltage sections as a vector, the state estimation circuit may determine the similarity between vectors stored in lookup tables and a vector regarding the subject battery to determine a state of health value of the subject battery.

The similarity may be determined according to the Euclidean distance. The state estimation circuit may calculate Euclidean distance values with respect to the vector regarding the subject battery and the respective vectors stored in the lookup tables. The state estimation circuit may determine a vector, having the lowest Euclidean distance value among calculated Euclidean distance values, as the vector having the highest similarity and determine an SOH corresponding to this vector as a state of health value of the subject battery.

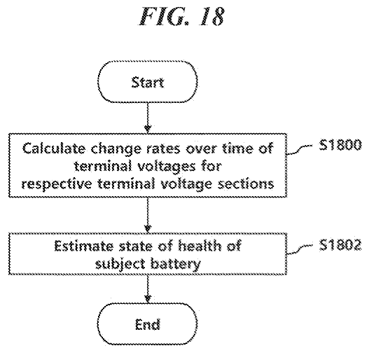

FIG. 18 is a flow diagram of a method for estimating a state of health of a battery according to a second embodiment.

Referring to FIG. 18, the estimation device may calculate change rates over time of terminal voltages regarding respective N (N is a natural number equal to or higher than 2) terminal voltage sections in the constant current charging mode of the subject battery (S1800).

The sizes of at least two of the N terminal voltage sections may be different from each other. For example, a first terminal voltage section may be a section corresponding to a range of 3.00V˜3.05V, of which the size is 0.05V, whereas a second terminal voltage section may be a section corresponding to a range of 3.05V˜3.15V, of which the size is 0.1V.

A section having a great change rate over time of the terminal voltage may have a size smaller than that of a section having a small change rate over time of the terminal voltage.

The estimation device may estimate a state of health of the subject battery by comparing the N change rates over time of terminal voltages calculated in the previously described stage with data of change rates over time of the terminal voltages stored depending on states of health (S1802).

The data of change rates over time of terminal voltages may comprise lookup tables in which change rates over time of terminal voltages in a plurality of terminal voltage sections are stored.

When estimating a state of health, the estimation device may search for, in the lookup table, data including change rates over time of terminal voltages having a high similarity to the N change rates over time of terminal voltages and determine a state of health value corresponding to the data as a state of health value of the subject battery.

When estimating a state of health, the estimation device may calculate Euclidean distance values with respect to the calculated N change rates over time of terminal voltages and the change rates over time of terminal voltages stored in the lookup table, search for data having the smallest Euclidean distance value, and determine a state of health value corresponding to the data as a state of health value of the subject battery.

Ranges of a plurality of terminal voltage sections of lookup tables may be wider than a range of the N terminal voltage sections for which calculations have been performed with respect to the subject battery.

When estimating a state of health, the estimation device may select a lookup table corresponding to the operation temperature of the subject battery among lookup tables included in data of change rates over time of terminal voltages and determine a state of health value of the subject battery based on the selected lookup table.

An embodiment of the present disclosure has an advantage that a state of health of a battery may efficiently be estimated even when the battery is partially charged and the relevant calculations are simple, which leads to allowing an online SOH estimation.

Since terms, such as “including,” “comprising,” and “having” mean that corresponding elements may exist unless they are specifically described to the contrary, it shall be construed that other elements can be additionally included, rather than that such elements are excluded. All technical, scientific, or other terms are used consistently with the meanings as understood by a person skilled in the art unless defined to the contrary. Common terms as found in dictionaries should be interpreted in the context of the related technical writings, rather than overly ideally or impractically, unless the present disclosure expressly defines them so.

Although a preferred embodiment of the present disclosure has been described for illustrative purposes, those skilled in the art will appreciate that various modifications, additions, and substitutions are possible without departing from the scope and spirit of the embodiment as disclosed in the accompanying claims. Therefore, the embodiments disclosed in the present disclosure are intended to illustrate the scope of the technical idea of the present disclosure, and the scope of the present disclosure is not limited by the embodiment. The scope of the present disclosure shall be construed on the basis of the accompanying claims in such a manner that all of the technical ideas included within the scope equivalent to the claims belong to the present disclosure.

What is claimed is:

1. A method for estimating a state of health of a battery, comprising:
storing, as reference charging times, charging times measured respectively in a plurality of terminal voltage sections for a battery in a reference state of health, which is charged with a constant current;
storing charging times respectively of N (N is a natural number equal to or higher than 2) terminal voltage sections as comparative charging times in a constant current charge mode of one battery and calculating ratio values of the comparative charging times to the reference charging times respectively for the N terminal voltage sections; and
estimating a state of health of the one battery by inputting the N ratio values into a pre-learned machine learning model.

2. The method of claim 1, wherein, in estimating a state of health of the one battery, a difference between an operation temperature of the one battery and a reference temperature is additionally inputted into the machine learning model.

3. The method of claim 1, wherein the sizes of the respective N terminal voltages sections are identical.

4. The method of claim 1, wherein, in estimating a state of health of the one battery, at least one terminal voltage value corresponding to the N terminal voltage sections is additionally inputted into the machine learning model.

5. The method of claim 1, wherein, in calculating ratio values, N voltage sections from a terminal voltage of the one battery checked at a time point may be set as the N terminal voltage sections.

6. The method of claim 1, wherein, in a case when the comparative charging times are measured with respect to M (M is a natural number higher than N) terminal voltage sections, in calculating ratio values, the N terminal voltage sections are set to include predetermined terminal voltage sections.

7. The method of claim 6, wherein, among the M terminal voltage sections, a charging time in one terminal voltage section belonging to the N terminal voltage sections is longer than a charging time in another terminal voltage section that does not belong to the N terminal voltage sections.

8. The method of claim 1, wherein the machine learning model comprises N sub machine learning models combined in a form of an ensemble, wherein each of the N sub machine learning models takes a ratio value of each terminal voltage section as an input and takes a state of health value as an output.

9. The method of claim 1, wherein the machine learning model comprises L (L is a natural number higher than N) sub machine learning models, each of which takes a ratio value of each terminal voltage section as an input and takes a state of health value as an output, each sub machine learning model may have its own order of priority, and
in estimating a state of health, the state of health of the one battery is estimated by a value outputted from a sub machine learning model having the highest order of priority among values outputted from N sub machine learning models, which correspond to the N terminal voltage sections, among the L sub machine learning models.

10. The method of claim 1, wherein at least two of the N terminal voltage sections have different sizes and reference charging times or comparative charging times in the at least two terminal voltage sections have sizes similar to each other within a predetermined margin of error.

11. A device for estimating a state of health of a battery comprising:
a storage circuit to store, as reference charging times, charging times measured respectively for a plurality of terminal voltage sections for a battery in a reference state of health, which is charged with a constant current;
a calculation circuit to store, as comparative charging times, charging times respectively for N (N is a natural number equal to or higher than 2) terminal voltage sections in a constant current charge mode of one battery and to calculate ratio values of the comparative charging times to the reference charging times respectively for the N terminal voltage sections; and
a state estimation circuit to estimate a state of health of the one battery by inputting the N ratio values into a pre-learned machine learning model.

12. The device of claim 11, wherein the state estimation circuit estimates a state of health of the one battery by additionally inputting into the machine learning model a difference between an operation temperature of the one battery and a reference temperature.

13. The device of claim 11, wherein the state estimation circuit estimates a state of health of the one battery by additionally inputting into the machine learning model at least one terminal voltage value corresponding to the N terminal voltage sections.

14. The device of claim 11, wherein the calculation circuit sets N voltage sections from a terminal voltage of the one battery, which is checked at a time point, as the N terminal voltage sections.

15. The device of claim 11, wherein, in a case when the comparative charging times are measured with respect to M (M is a natural number higher than N) terminal voltage sections, the calculation circuit sets the N terminal voltage sections to include predetermined terminal voltage sections.
